(19) United States
(12) Patent Application Publication
(10) Pub. No.: US 2007/0249141 A1
(43) Pub. Date: Oct. 25, 2007

(54) Method of manufacturing electrode pattern

(76) Inventors: Young Woo Lee, Suwon (KR); Jeong Min Cho, Seongnam (KR); Hang Kyu Cho, Yongln (KR)

Correspondence Address: MCDERMOTT WILL & EMERY LLP, 600 13TH STREET, N.W., WASHINGTON, DC, 20005-3096, US

(21) Appl. No.: 11/785,578

(22) Filed: Apr. 18, 2007

(30) Foreign Application Priority Data
Apr. 18, 2006 (KR) 10-2006-0035143

(51) Int. Cl. H01L 21/00; H01L 21/30

(52) U.S. Cl. 438/458; 438/20

(57) ABSTRACT

A method of manufacturing an electrode pattern comprises preparing a first support film; forming a mold release pattern on one surface of the first support film, the mold release pattern defining an internal electrode formation region; forming an electrode layer on the mold release pattern by using a thin film technique; preparing a second support film; forming a transfer target layer on one surface of the second support film; disposing the electrode layer of the first support film and the transfer target layer of the second support film such that the electrode layer and the transfer target layer face each other; thermally compression-bonding the first and second films disposed to face each other such that the electrode layer positioned on the mold release pattern is transferred onto the transfer target layer; and separating the first and second films from each other.

### CROSS-REFERENCE TO RELATED APPLICATIONS

This application claims the benefit of Korean Patent Application No. 10-2006-0035143 filed with the Korean Intellectual Property Office on Apr. 18, 2006, the disclosure of which is incorporated herein by reference.

### BACKGROUND OF THE INVENTION

1. Field of the Invention

The present invention relates to a method of manufacturing an electrode pattern which is suitable for forming an internal electrode in a process of manufacturing laminate-type electronic parts.

2. Description of the Related Art

In general, laminate-type electronic parts are electric elements formed by repeatedly laminating ceramic layers and electrode layers. As for the laminate-type electronic parts, there are provided condensers, inductors, resistors, magnetic substances, filters and the like.

The electrode layer is roughly divided into an internal electrode formed inside a laminate-type electronic part and an external electrode formed outside. In accordance with the recent tendency where laminate-type electronic parts are manufactured to be light, slim, and small, a thin film technique is required in order to reduce the thickness of the internal electrode.

Conventionally, an internal electrode is formed by a thick film process, such as a screen printing method using metallic powder manufactured of paste or a gravure printing method using metallic powder manufactured of slurry.

In the screen printing method and the gravure printing method, an internal electrode pattern is formed in a screen wound in a roll shape or gravure. Therefore, a separate process for patterning an internal electrode can be omitted so that the overall manufacturing process of internal electrode can be simplified. However, since the metallic powder is manufactured of paste or slurry, there has been a technical limit in forming the internal electrode having a uniform thickness of less than 1 μm.

In order to overcome such a limit in the screen printing method or the gravure printing method, a vacuum thin film technique has been adopted in which the thickness of an internal electrode can be adjusted in A scale, that is, nanometer scale.

Although the internal electrode manufactured according to the vacuum thin film technique can have a thickness of less than 1 μm, the internal electrode is patterned through a separate process such as an optical lithography method. Therefore, a process time for forming one layer of internal electrode is lengthened.

In other words, when such a vacuum thin film technique is applied to a process of manufacturing a laminate-type electronic part requiring several-hundred layers of internal electrodes, the overall process of manufacturing a laminate-type electronic part increases in time. As a result, a production yield of the laminate-type electronic parts decreases.

### SUMMARY OF THE INVENTION

An advantage of the present invention is that it provides a method of manufacturing an electrode pattern, in which several-hundreds layers of electrode patterns required by a laminate-type electronic part can be patterned to have a thickness of less than 1 μm in a short time.

Additional aspect and advantages of the present general inventive concept will be set forth in part in the description which follows and, in part, will be obvious from the description, or may be learned by practice of the general inventive concept.

According to an aspect of the invention, a method of manufacturing an electrode pattern comprises preparing a first support film; forming a mold release pattern on one surface of the first support film, the mold release pattern defining an internal electrode formation region; forming an electrode layer on the mold release pattern by using a thin film technique; preparing a second support film; forming a transfer target layer on one surface of the second support film; disposing the electrode layer of the first support film and the transfer target layer of the second support film such that the electrode layer and the transfer target layer face each other; thermally compression-bonding the first and second films disposed to face each other such that the electrode layer positioned on the mold release pattern is transferred onto the transfer target layer; and separating the first and second films from each other.

According to another aspect of the invention, the mold release pattern is formed by using a printing method selected from a group consisting of a screen printing method, a gravure printing method, an ink-jet printing method, and a laser printing method.

According to a further aspect of the invention, the mold release pattern is formed of a mixture containing one polymer selected from a polymer group consisting of ethylcellulose-based polymer, acrylic polymer, and PVB-based polymer. The mixture further includes plasticizer for lowering compression temperature. As for the plasticizer, non-phthalate plasticizer is used.

According to a still further aspect of the invention, the mixture further includes silicon-based mold release accelerator in order to increase a mold release property.

According to a still further aspect of the invention, the mixture further includes ceramic power, in order to secure stability to the heat when the thermo-compression bonding is performed.

According to a still further aspect of the invention, the thermal compression-bonding of the first and second films is performed in a vacuum compression chamber, thereby removing bubbles generated at the interface between the electrode layer and the transfer target layer.

According to a still further aspect of the invention, the thermal compression-bonding of the first and second films is performed in humidity ranging from 0% to 50%. Then, it is possible to increase an interface compression-bonding force between the electrode layer and the transfer target layer.

According to a still further aspect of the invention, the method further comprises forming a mold release layer on one surface of the first support film, before the forming of the mold release pattern. The mold release layer is formed of a mixture containing low-molecular silicon-based oil. The mixture further contains silicon-based mold release accelerator.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1A to 1E are sectional views sequentially showing a process for explaining a method of manufacturing an electrode pattern according to a first embodiment of the invention;

FIG. 2 is a graph showing a change in compression time in accordance with a change in plasticizer content added into a mold release pattern of the invention;

FIG. 3 is a graph showing a change in transfer rate in accordance with a compression time of a mold release pattern into which plasticizer is added;

FIG. 4 is a graph showing a change in transfer rate in accordance with a compression time of a mold release pattern into which plasticizer and plasticizer accelerator are added; and

FIG. 5 is a sectional view showing a process for explaining a method of manufacturing an electrode pattern according to a second embodiment of the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a method of manufacturing an electrode pattern according to an embodiment of the present invention will be described in detail with reference to the accompanying drawings.

### First Embodiment

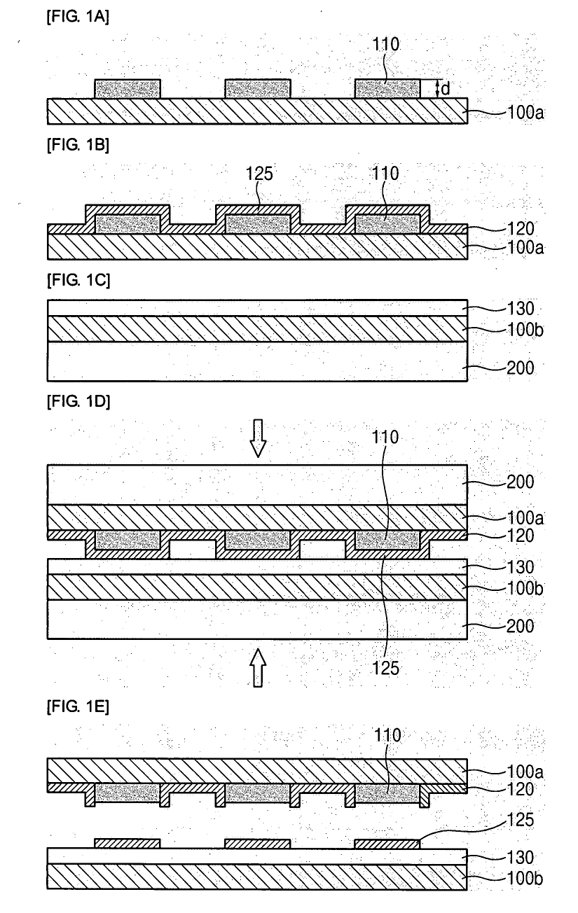

First, a method of manufacturing an electrode pattern according to a first embodiment of the invention will be described with reference to FIGS. 1A to 1E.

FIGS. 1A to 1E are sectional views sequentially showing a process for explaining the method of manufacturing an electrode pattern according to the first embodiment of the invention.

As shown in FIG. 1A, a first support film 100a composed of PET, PBT or the like is prepared.

Next, a mold release pattern 110 is formed on one surface of the first support film 100a, the mold release pattern 110 defining an internal electrode formation region.

More specifically, the mold release pattern 110 is formed as follows. First, mold release forming liquid is printed in a desired pattern, that is, in a shape of an internal electrode pattern on one surface of the first support film 100a by a printing method such as screen printing, gravure printing, ink-jet printing, laser printing or the like. Next, the printed mold release forming liquid is dried by a hot wind of 80 to 100° C. The thickness of the mold release pattern 110 formed by the above-described printing method has an effect on transfer efficiency and the precision of an internal electrode which is transferred and formed, when a thermo-compression bonding transfer process to be described below is performed. Therefore, the mold release pattern 110 is formed so that the thickness thereof is properly adjusted by using a characteristic of a printing method depending on a process condition.

As for the mold release forming liquid, a mixture containing ethylcellulose-based polymer, acrylic polymer, or PVB-based polymer is preferably used.

In this embodiment, a mixture containing ethylcellulose-based polymer among them is used as the mold release forming liquid. The mixture can further enhance a pattern formation property of mold release pattern and resolution, compared with a mixture containing low-molecular-weight silicon-based oil which is general mold release forming liquid.

Preferably, the mold release forming liquid further includes plasticizer which can adjust viscosity and decrease compression temperature in a printing process. As for the plasticizer, there are provided phthalate-based plasticizer and non-phthalate plasticizer.

Considering the compatibility with the mixture containing ethylcellulose-based polymer, a large amount of phthalate-based plasticizer is needed in order to obtain a plasticization effect, because the phthalate-based plasticizer has low compatibility. On the contrary, since the non-phthalate plasticizer has high compatibility, an excellent plasticization effect can be obtained, even though a small amount of non-phthalate plasticizer is used. Therefore, in this embodiment, the non-phthalate plasticizer is preferably used as the above-described plasticizer.

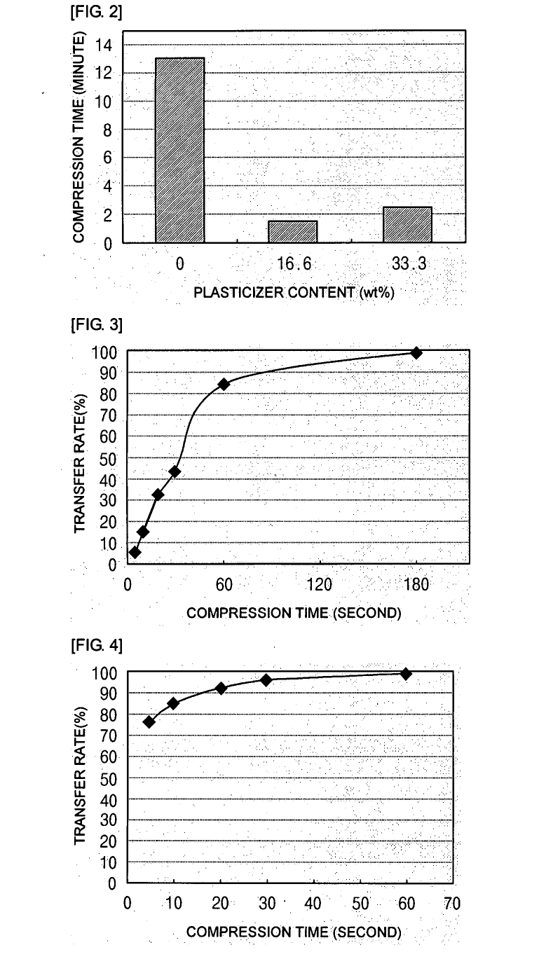

FIG. 2 is a graph showing a change in compression time in accordance with a change in plasticizer content added into the mold release pattern of the invention. More specifically, FIG. 2 comparatively shows the respective compression times of a mold release pattern into which plasticizer is added by 0 wt %, a mold release pattern into which plasticizer is added by 16.6 wt %, and a mold release pattern into which plasticizer is added by 33.3 wt %. As shown in FIG. 2, the compression time of the mold release pattern into which plasticizer is added by 33.3 wt % is smaller than that of the mold release pattern into which plasticizer is added by 0 wt %, and the compression time of the mold release pattern into which plasticizer is added by 16.6 wt % is smaller than that of the mold release pattern into which plasticizer is added by 33.3 wt %. In this embodiment, when plasticizer is added by 10 to 30 wt % with respect to the overall mold release forming liquid, it is possible to obtain an excellent plasticization effect.

Preferably, the mold release forming liquid further includes a silicon-based mold release accelerator in order to enhance a mold release property. In this embodiment, dimethylsiloxane polymer is used as the silicon-based mold release accelerator.

The mold release accelerator substitutes the surface of the mold release pattern 110 with silicon and thus interferes the absorption of an electrode layer coming in contact with the surface of the mold release pattern 110. Then, when a subsequent thermo-compression bonding transfer process is performed, the electrode layer can be easily peeled off from the surface of the mold release pattern, thereby reducing a transfer time. This can be found in FIGS. 3 and 4.

FIG. 3 is a graph showing a change in transfer rate in accordance with a compression time of a mold release pattern into which plasticizer is added, and FIG. 4 is a graph showing a change in transfer rate in accordance with a compression time of a mold release pattern into which plasticizer and plasticizer accelerator are added. Referring to FIGS. 3 and 4, it can be found that the transfer rate according to the compression time of the mold release pattern in which plasticizer and plasticizer accelerator are added is more excellent than the transfer rate according to the compression time of the mold release pattern in which only plasticizer is added.

The addition of plasticizer accelerator can be omitted depending on a process condition and a characteristic of the mold release forming liquid.

Preferably, the mold release forming liquid further includes ceramic powder in order to prevent the chemical combination of the previously-formed mold release pattern from being transformed due to high temperature followed by an electrode layer formation process using a vacuum thin film technique and a thermo-compression bonding process, which will be subsequently performed. That is, the ceramic powder serves to prevent the condensation of polymer of the mold release forming liquid composed of a mixture containing ethylcellulose-based polymer. Further, the ceramic powder serves to maintain a stable interface state at the contact interface with an electrode layer to be formed in the following process.

Subsequently, as shown in FIG. 1B, an electrode layer 120 is formed on the resulting structure, in which the mold release pattern 110 is formed, by a thin film technique. At this time, the thin film technique is such a technique that the thickness of the electrode layer 120 can be adjusted in nanometer scale (nm). As for the thin film technique, there are provided a vacuum deposition method, a sputtering method, a chemical vapor deposition method and the like.

In FIG. 1B, reference numeral 125 represents an electrode layer which is positioned only on the mold release pattern 110, in order to more clearly explain the method of manufacturing an electrode according to the invention.

As shown in FIG. 1C, a second support film 100b composed of PET, PBT or the like is then prepared. On one surface of the second support film 100b, a transfer target layer 130 is formed. In this embodiment, a green sheet is used as the transfer target layer 130.

Subsequently, as shown in FIG. 1D, the electrode layer 120 of the first support film 100a and the transfer target layer 130 of the second support film 100b are disposed so as to face each other.

The electrode layer 120 of the first support film 100a and the transfer target layer 130 of the second support film 100b, disposed so as to face each other, are thermally compression-bonded in an arrow direction by using thermo-compression bonding plates 200 provided on the respective outer surfaces thereof. This process is where the mold release pattern 110 is activated so that the electrode layer 125 positioned thereon is transferred onto the surface of the transfer target layer 130 of the second support film 100b.

Meanwhile, when the thermo-compression bonding process is performed, and if a compression bonding area is wide and a compression bonding time is short, the gas which is already present at the interface between the electrode layer 125 and the transfer target layer 130 is fixed during the interval so as to form circular bubbles. Such bubbles make pressure transmission non-uniform, thereby interfering the transfer of the transfer layer 120.

Therefore, the moment the compression bonding is performed while the thermo-compressing bonding process is performed in a vacuum compression bonding chamber, atmosphere pressure is lowered by using a vacuum pump so as to remove bubbles generated at the interface between the electrode layer 120 and the transfer target layer 130. Then, compression bonding efficiency is increased.

When the electrode layer 125 and the transfer target layer 130 are thermally compression-bonded, humidity ranging from 0% to 50% is maintained in the vacuum compression chamber. Then, an interface compression-bonding force between the electrode layer 125 and the transfer target layer 130 is enhanced.

Next, as shown in FIG. 1E, the first and second support films 100a and 100b are separated. Then, the electrode layer 125 positioned on the mold release pattern 110 is selectively transferred onto the transfer target layer 130. At this time, the transferred electrode layer 125 serves as an internal electrode.

In this embodiment, the characteristic of the mold release pattern, the vacuum thin film technique, and the thermo-compression bonding transfer method are used so that a laminate-type electronic part requiring several hundred layers of internal electrodes is reduced in size, and simultaneously, the overall manufacturing process is reduced in time. Then, a production yield is increased. In the characteristic of the mold release pattern, when the electrode layer and the first support film is prevented from being combined and the temperature is increased to more than normal temperature, fluidity is provided so that the electrode layer positioned on the pattern is easily separated from the first support film. In the vacuum thin film technique, the thickness of the electrode layer can be adjusted in nanometer scale. The thermo-compression bonding process can simplify the process.

### Second Embodiment

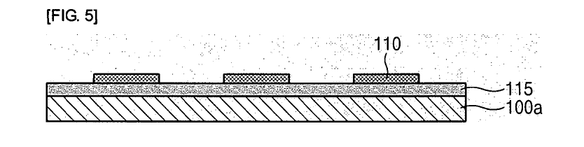

Now, a method of manufacturing an electrode pattern according to a second embodiment of the invention will be described with reference to FIG. 5. However, the descriptions of the same components of the second embodiment as those of the first embodiment will be omitted.

FIG. 5 is a sectional view for explaining the method of manufacturing an electrode pattern according to the second embodiment of the invention.

The method of manufacturing an electrode pattern according to the second embodiment has almost the same construction as the method of manufacturing an electrode pattern according to the first embodiment. As shown in FIG. 5, however, the method of an electrode pattern according to the second embodiment further includes forming a mold release layer 115 on one surface of the first support film 100a, before the mold release pattern 110 defining an internal electrode formation region is formed on the one surface of the first support film 100a.

The release layer 115 is formed of a mixture containing low-molecular silicon-based oil. Depending on a process characteristic and a process condition, silicon-based mold release accelerator can be further included in the mixture.

Such a mold release layer 115 is positioned at the interface between the first support film 100a and the mold release pattern 110 so as to stabilize interface energy of the mold release pattern, which has increased due to the silicon-based release accelerator contained to increase a mold release property.

In this embodiment, the mold release pattern 110 formed on the release layer 115 can be formed to have a smaller thickness than the mold release pattern according to the first embodiment (refer to FIG. 1A), through the mold release layer 115.

In this embodiment, the same operation and effect as the first embodiment can be obtained. Further, the reliability of the thermo-compressing bonding transfer process can be enhanced by the release layer 115.

According to the present invention, there is provided the method of manufacturing an electrode pattern, in which several-hundred layers of electrode patterns required by a laminate-type electronic part can be patterned at a thickness of less than 1 μm in a short time.

Accordingly, a laminate-type electronic part requiring several-hundred layers of electrode patterns can be reduced in size, and simultaneously, the overall manufacturing process can be reduced in time such that a production yield is increased.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing an electrode pattern comprising:
preparing a first support film;
forming a mold release pattern on one surface of the first support film, the mold release pattern defining an internal electrode formation region;
forming an electrode layer on the mold release pattern by using a thin film technique;
preparing a second support film;
forming a transfer target layer on one surface of the second support film;
disposing the electrode layer of the first support film and the transfer target layer of the second support film such that the electrode layer and the transfer target layer face each other;
thermally compression-bonding the first and second films disposed to face each other such that the electrode layer positioned on the mold release pattern is transferred onto the transfer target layer; and
separating the first and second films from each other.

2. The method according to claim 1,
wherein the mold release pattern is formed by using a printing method selected from a group consisting of a screen printing method, a gravure printing method, an ink-jet printing method, and a laser printing method.

3. The method according to claim 1,
wherein the mold release pattern is formed of a mixture containing one polymer selected from a polymer group consisting of ethylcellulose-based polymer, acrylic polymer, and PVB-based polymer.

4. The method according to claim 3,
wherein the mixture further includes plasticizer for lowering compression temperature.

5. The method according to claim 4,
wherein as for the plasticizer, non-phthalate plasticizer is used.

6. The method according to claim 3,
wherein the mixture further includes silicon-based mold release accelerator.

7. The method according to claim 3,
wherein the mixture further includes ceramic power.

8. The method according to claim 1,
wherein the thermal compression-bonding of the first and second films is performed in a vacuum compression chamber.

9. The method according to claim 1,
wherein the thermal compression-bonding of the first and second films is performed in humidity ranging from 0% to 50%.

10. The method according to claim 1 further comprising
forming a mold release layer on one surface of the first support film, before the forming of the mold release pattern.

11. The method according to claim 10,
wherein the mold release layer is formed of a mixture containing low-molecular silicon-based oil.

12. The method according to claim 11,
wherein the mixture further contains silicon-based mold release accelerator.
